(19) United States
(12) Patent Application Publication
(10) Pub. No.: US 2017/0080299 A1
(43) Pub. Date: Mar. 23, 2017

(54) Article with Metallic Strip and Method of Making Same

(71) Applicant: Dunlop Sports Company Limited, Kobe (JP)

(72) Inventors: Nick Trahan, Huntington Beach, CA (US); Phill Seagram, Huntington Beach, CA (US); Keith Dolezel, Huntington Beach, CA (US); Mika Becktor, Huntington Beach, CA (US)

(21) Appl. No.: 15/369,424

(22) Filed: Dec. 5, 2016

Related U.S. Application Data
(63) Continuation of application No. 14/477,630, filed on Sep. 4, 2014.

(51) Int. Cl. A63B 53/04; C23C 14/04; C23C 14/02; C23C 14/24; C23C 14/34

(52) U.S. Cl. CPC A63B 53/04; A63B 53/047; C23C 14/24; C23C 14/34; C23C 14/028; C23C 14/042; A63B 2053/0433

(57) ABSTRACT

An article, such as a golf club head, comprising one or more of a polished region, a textured region, a painted region, and/or a coated region, which may be formed using one or more masking operations, texturing operations, painting operations, and mask removal operations. A liquid mask may be applied over a narrow region defined by opposing mask edges, enabling a strip of a metallic surface to be framed by painted, textured, and/or coated regions.

### CROSS-REFERENCE TO RELATED APPLICATIONS

Not Applicable

### STATEMENT RE: FEDERALLY SPONSORED RESEARCH/DEVELOPMENT

Not Applicable

### COPYRIGHT AUTHORIZATION

The disclosure below may be subject to copyright protection. The copyright owner has no objection to the facsimile reproduction by any one of the documents containing this disclosure as they appear in the Patent and Trademark Office records, but otherwise reserves all applicable copyrights.

### BACKGROUND OF THE INVENTION

1. Field of the Invention

The present disclosure relates to articles of manufacture and methods of making the same, including by way of example, golf club heads.

2. Description of the Related Art

Product manufacturers of all types are constantly looking for ways to attract attention to their wares, whether by applying to them distinctive colors, shapes, textures, finishes, paints, coatings, or otherwise. But more distinctive looks, particularly those that appear “custom” often require significant manual labor, expensive manufacturing processes, and other techniques, the effectiveness and repeatability of which may be highly dependent on variable skills of assemblers, craftsmen, or artisans.

Some products, for example, golf clubs, often depend on appearance as a means of communicating to the consumer quality, performance, and style, and, because confidence is such an important attribute of a golfer's performance, golf club manufacturers often attempt to instill confidence in the golfer by providing golf clubs that look good, stylish, unique, or inviting at the point of sale, at address, or even while in the bag.

One way to achieve a distinctive look on an article such as a golf club head may include providing a physical vapor disposition (PVD) coated or painted head, for example, with a matt black finish and/or texture, and providing a contrasting portion that may provide visual “pop” such as a highly polished metallic portion. But heretofore, providing such high contrasts was not economically feasible, as it would have required, for example, positioning a polished metal inlay in a complimentary recess in the article, which would involve significant labor and could result in issues relating to fit and finish of the article. Other prior methods may involve numerous painting and/or PVD coating steps, adding to labor and material costs.

### BRIEF SUMMARY OF THE INVENTION

An article, such as a golf club head, may comprise a back, a sole and, a face, wherein the sole may comprise a first region proximate the face, and wherein the first region may comprise a PVD-coated surface; a second region proximate the back, wherein the second region may comprise a PVD-coated surface; and a third region between the first and second region that may comprise a polished metallic surface that is substantially free of a PVD coating.

A method is disclosed, which may comprise one or more operations including: polishing an article, which may comprise a sole of a golf club head, the golf club head comprising the sole, a face, and a back; applying a first mask to the sole, the first mask covering a first portion of the sole, while leaving uncovered a second portion of the sole; applying a texture to the second portion of the sole, thereby forming a textured region having a texture boundary defined by the first mask; removing the first mask; applying a second mask covering at least a portion of the textured region; applying a third mask covering at least a portion of a first polished region of the first portion of the sole and leaving exposed a second polished region of the first portion of the sole; applying a liquid mask substantially covering the second polished region of the first portion of the sole; removing the second mask and the third mask from the sole; applying a paint or coating to substantially the entire sole; and removing the liquid mask from the second polished region of the first portion of the sole.

### BRIEF DESCRIPTION OF THE DRAWINGS

The features, obstacles and advantages of the present application will become more apparent from the detailed description set forth below when taken into conjunction with the drawings, wherein:

FIG. 1 illustrates a plan view of an article, comprising a golf club head of the disclosure.

FIG. 2 illustrates an isometric view of the article of FIG. 1.

FIG. 3 illustrates the article of FIG. 1 from a frontal perspective, showing the face thereof.

FIG. 4 illustrates a detail of the circled portion of FIG. 1.

FIG. 5 illustrates a flow chart illustrating a method of the disclosure.

FIG. 6 illustrates a flow chart illustrating another method of the disclosure.

FIG. 7 illustrates a method of applying a mask according to the present disclosure.

FIG. 8 illustrates another aspect of a method of applying one or more masks according to the present disclosure.

FIG. 9 illustrates an end view of a golf club head according to another embodiment of the disclosure.

FIG. 10 illustrates a plan view of the golf club head of FIG. 9.

FIG. 11 illustrates an isometric view of the golf club head of FIG. 9.

FIG. 12 illustrates a detail of the circled portion of FIG. 9.

### DETAILED DESCRIPTION OF THE INVENTION

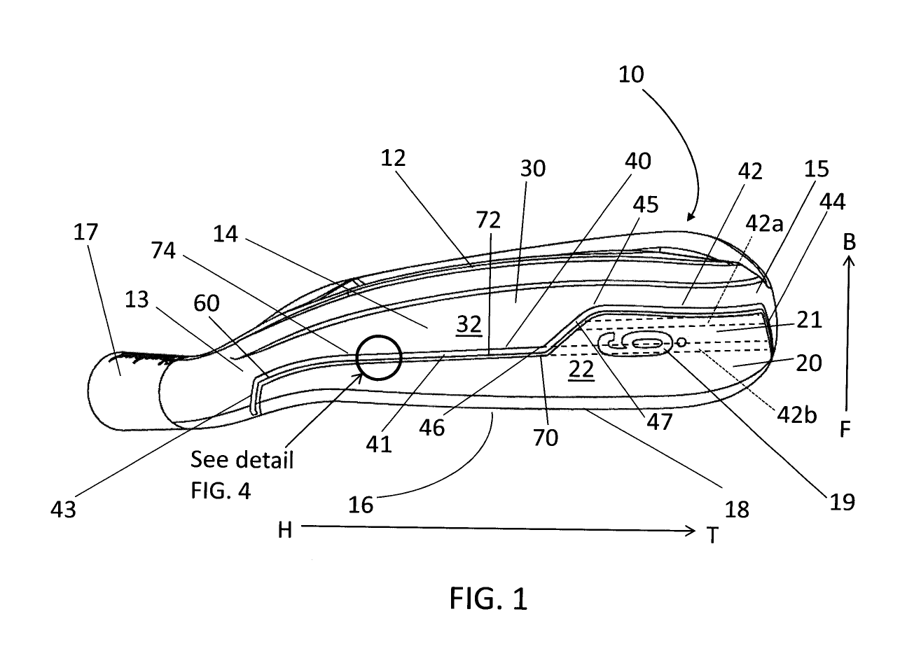

Referring to FIGS. 1-3, there is illustrated a golf club head, generally 10 comprising a back 12, a sole 14, and a face 16 opposite the back 12 with which to hit a golf ball (not shown). The golf club head 10 additionally includes a heel 13 and a toe 15 disposed adjacent opposed end portions of the club head 10, wherein the face 16 generally extends between the heel 13 and the toe 15. The golf club head 10 generally also includes a hosel 17, and may include a numeric or other indicator 19, identifying the club, in this example, a 6-iron. While an iron-type golf club head 10 is illustrated, the disclosure is not limited to iron-type golf club heads. The term “golf club head” as used herein is, unless otherwise limited by a particular claim or context of use, thus intended to mean drivers, fairway woods, hybrids, irons, wedges, and putters. The sole 14 typically merges with the face 16 via a face leading edge 18, which may comprise a sharp corner or a radius. The back 12, in the case of a putter or iron-type golf club head 10 may comprise a plaque, (not shown), for providing vibration damping, graphics, and/or branding indicia, as is known.

As illustrated, the golf club head 10 may comprise a first region 20 proximate the face 16. The first region 20 may thus reside on a frontal portion of the sole 14. The first region 20 may comprise a relatively rough surface associated with a first surface roughness value, such as a textured surface 22. The textured surface 22 may be formed on the golf club head 10 using known methods, such as sandblasting, chemical etching, grinding, for example with an abrasive grinding wheel, brushing, and/or tumbling. In a preferred aspect, the texturing may be achieved using a mask, such as a die-cut masking tape, to at least partially define the first region 20 and/or to shield other regions of the golf club head 10 from being textured. As used herein, the term “mask” means any material that may be used to mask or effectively cover a surface from receiving a treatment such as painting, texturing, coating, coloring, polishing, and the like. Thus, a mask may comprise, for example, a tape, foil, shield, or layer, including layers formed by vapor deposition, applying a liquid and allowing it to dry, etc. The first region 20 may be painted or coated, for example, after texturing, using known paints, coatings, and methods, including PVD (physical vapor deposition) coating.

As used herein, the term “PVD” includes both the process of applying a PVD coating and the resultant coating. As is known, PVD describes a variety of vacuum deposition methods used to deposit thin films by the condensation of a vaporized form of the desired film material onto various workpiece surfaces (e.g., onto semiconductor wafers, golf clubs, aerospace components, etc.). At the same time as high vaccum and heat is applied to the workpiece, which may be placed inside a rig, a reactive gas (e.g. nitrogen or a gas containing carbon) is introduced. The reactive gas forms a compound with the metal vapor and is deposited on the tools or components as a thin, highly adherent coating. In order to obtain a uniform coating thickness, the parts are generally rotated at uniform speed about several axes.

The PVD coating method typically involves purely physical processes such as high-temperature vacuum evaporation with subsequent condensation, or plasma sputter bombardment rather than involving a chemical reaction at the surface to be coated as in chemical vapor deposition. Common materials used for coatings applied by PVD are titanium nitride, zirconium nitride, chromium nitride, and titanium aluminum nitride. PVD coatings are generally thin, but durable, and abrasion and wear resistant, which are important aspects of golf club design.

In a preferred aspect, PVD coatings such as those available, for example, through the Shenzhen Zhongji Vacuum Plating Company, Ltd., No. 1 BanAn Street, Sha Tian Industrial Estate, HouTing Road, Sha Jing Town, Shenzhen, China, may be used for coating golf club heads in order to achieve different colors and finishes, including by way of example, yellow gold, rose gold, red, blue, white, tin, gray, titanium, brown, gun metal, and black, in finishes of brushed, mirror polished, and blast finishes.

Variants of PVD include coating methods such as, Cathodic Arc Deposition, in which a high-power electric arc discharged at the target (source) material blasts away some into highly ionized vapor to be deposited onto the workpiece. Another PVD variant includes Electron Beam Physical Vapor Deposition, in which the material to be deposited is heated to a high vapor pressure by electron bombardment in “high” vacuum and is transported by diffusion to be deposited by condensation on the (cooler) workpiece. Evaporative Deposition is a further PVD variant, in which the material to be deposited is heated to a high vapor pressure by electrically resistive heating in “low” vacuum. Pulsed Laser Deposition is another PVD variant, in which a high-power laser ablates material from the target into a vapor. Yet another PVD variant includes Sputter Deposition, in which a glow plasma discharge (usually localized around the “target” by a magnet) bombards the material sputtering some away as a vapor for subsequent deposition.

In the case of applying a PVD coating to a golf club head, a golf club head or part may be placed in a vacuum, and in this vacuum chamber may be a secondary large slab or rod of material, such as, for example, one of the PVD materials described above or others known to those of skill in the art. The temperatures in the vacuum chamber may be raised to a certain degree such that the physical composition of the secondary slab/rod is altered and particles from the slab detach themselves, and reattach to the part (i.e., golf club head) resulting in a new color (for example, black). The vacuums and temperatures at which the rig or vacuum chamber is used during the PVD process are well known to those of ordinary skill in the art of PVD processing, but may be at high vacuum and temperature, for example, pressures as low as 1 torr, and temperatures of about 150-500° C.

As further illustrated in FIGS. 1 and 2, the golf club head 10 may comprise a second region 30 proximate the back 12. The second region 30 may thus reside substantially along a rearward portion of the sole 14. The second region 30 may comprise a relatively smooth surface associated with a second surface roughness value, which according to one aspect of the disclosure is less than the first surface roughness value. The relatively smooth surface of the second region 30 may be a polished surface 32. In this aspect, the polished surface 32 may be achieved using known methods. For example, the entire golf club head 10 may be nickel plated and the resulting nickel plate may be polished using a buffing wheel and/or liquid polish or other known techniques. The second region 30 may also be painted or coated, also using known paints, coatings, and methods, including PVD coating.

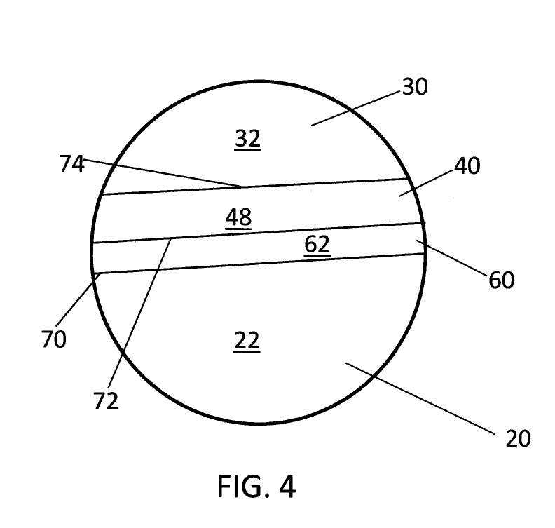

As further illustrated in FIGS. 1 and 2, the golf club head 10 may comprise a third region 40. The third region 40 may be positioned generally between the first region 20 and the second region 30. The third region 40 may comprise a polished metallic surface 48, as seen in detail in FIG. 4. Such a polished metallic surface 48 may be achieved, for example, by polishing a nickel-plated golf club head 10 and masking off the third region 40, for example, with a liquid mask that is allowed to dry. Thereafter, the golf club head 10 may be subjected to a painting or coating operation such that the first region 20 and second region 30 are painted or coated, for example with a PVD coating. Thereafter, when the PVD coating has dried or otherwise set, for example, the liquid mask may be removed from the golf club head 10 revealing the polished metallic surface 48 of the third region 40. Of course, other variations are possible. For example, the first region 20 and second region 30 may be masked as unpainted or uncoated surfaces, leaving only the third region 40 exposed. Paint, or a coating such as PVD, or texturing, such as by sandblasting, may then be applied to the third region 40, rendering it the only painted, coated, and/or textured surface, respectively, on the golf club head 10. Other combinations are of course possible.

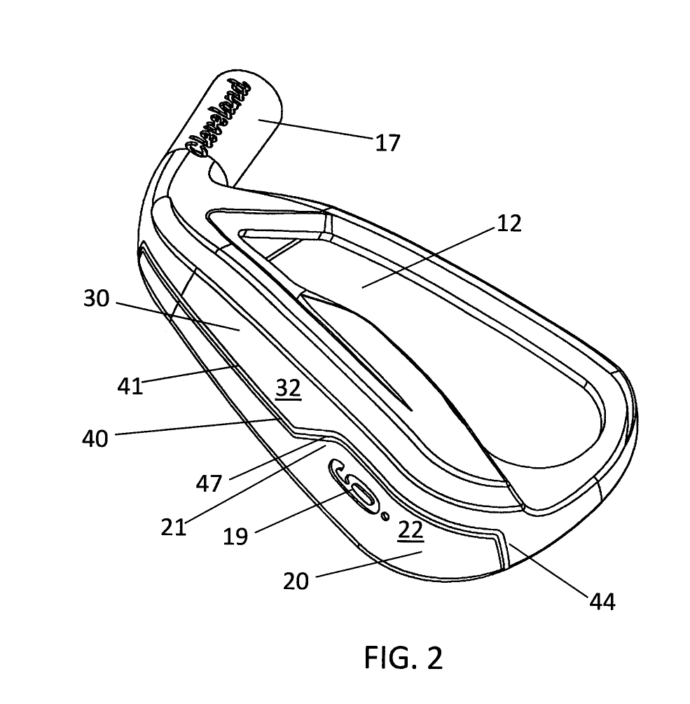

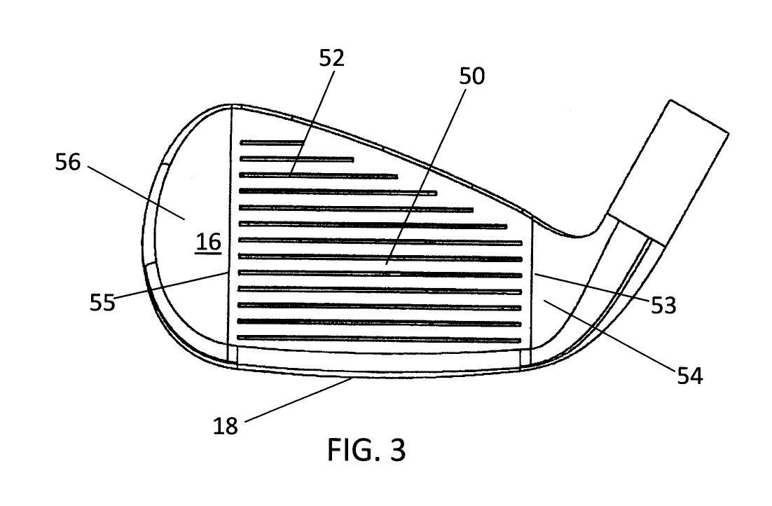

In another aspect, best seen in FIG. 3, the golf club head 10 may comprise a fourth region 50, which may comprise at least a portion of the face 16. The fourth region 50 may be textured and/or painted and/or coated substantially the same as the first region 20. In one aspect, both the first region 20 and fourth region 50 may be textured with the same texturing and painted with the same paint, or coated with the same coating, such as PVD, to achieve a uniform look between at least a portion of the sole 14 and face 16 and the face leading edge 18. In a preferred aspect, the fourth region 50 may comprise only that portion of the face 16 that contains grooves 52, as defined by lines 53, 55, which region may be textured, while the heel portion 54 and toe portion 56 of the face 16 may remain polished and un-textured. Such differentiation between textured surfaces, defined for example by the fourth region 50, and untextured surfaces, defined by the heel portion 54 and toe portion 56, may be achieved, for example, by masking off the surfaces to remain untextured and texturing the exposed surface.

Referring again to FIGS. 1 and 2, the third region 40 may comprise a thin strip that may be of substantially uniform width. The third region 40 may comprise one or more substantially linear sections. As illustrated, at least a portion of the one or more of the substantially linear sections, 41 and 42, may run generally in a heel-to-toe direction H→T of the sole 14. As illustrated, the substantially linear section 41 may be offset from the substantially linear section 42 such that the latter is reward of the former. As further illustrated, at least a portion of the one or more substantially linear sections 43 and 44, may run in a generally face-to-back direction F→B of the sole 14. As further illustrated, the third region 40 may comprise one or more curvilinear sections 45. The third region 40 may further comprise one or more angular sections, 46, comprising a juncture of two substantially linear sections 41, 47. As further illustrated, one or more of the linear sections may comprise a generally diagonal section 47 that may run diagonally relative to the heel-to-toe direction H→T and/or the front-to-back direction F→B.

The third region 40, particularly when formed as a relatively thin line as illustrated in FIGS. 1-4, may be used to more effectively depict/communicate various properties of the golf club head 10, such as relative degree of toe weighting, bounce, moment of inertia (MOI), heel weighting, center weighting, etc. In the example of FIGS. 1 and 2, as illustrated, the third region 40 may comprise a strip or ribbon that may comprise or define a visual indication, such as a jog section 21 that may jog reward from the face 16 proximate the toe 15 of the club head 10, represented by substantially linear sections 42 and 44. In this example, such a visual indication may indicate to the golfer that the golf club head 10 exhibits a high degree of toe weighting. Different fitting options might be provided, for example, by offering different clubs communicating different degrees of such a reward jog to the third region 40, such as illustrated by dotted line section 42a, representing a golf club head 10 with relatively less toe weighting, and dotted line region 42b representing a golf club head 10 with relatively even less toe weighting or with more balanced weighting compared to the golf club head of FIG. 1 comprising the solid line third region 40. Of course, in the example of dotted line region 42b, it may be necessary to move the numeric or other indicator 19 so the third region 40 does not pass through or too near it. Other variations are of course possible. For example, the third region 40 may comprise a rearward (or forward) jog proximate the center of the sole 14 having a pair of generally diagonal or rearwardly directed sections 47 presenting, for example, a central “stepped” region that may suggest, for example, a more centrally weighted club or may communicate a particular MOI for the club, such as high MOI or low MOI.

As further illustrated in FIGS. 1 and 2, and best seen in FIG. 4, the golf club head 10 may comprise a fifth region 60. The fifth region 60 may comprise a polished surface 62 that may be substantially the same as the polished surface 32 of the second region 30. In this aspect, the fifth region 60 may be painted, or coated, for example, using PVD, to achieve substantially the same look as the polished surface 32 of the second region 30. This may be achieved by a masking step in which the first region 20, after being textured, is masked to include an offset comprising the fifth region 60. A second mask may then be applied to the second region 30, thereby leaving exposed the third region 40, which may be masked with a liquid mask as previously described. After the liquid mask has dried, the mask covering the first region 20 and the offset corresponding to the fifth region 60 may be removed, and the mask covering the second region 30 may be removed, and the entire club head may be painted, or coated, for example with PVD. Then, the liquid mask may be removed, for example, by immersing the golf club head 10 in a solvent bath.

As illustrated and best seen in FIG. 4, the fifth region 60 may reside between the first region 20 and the third region 40. When the first region 20 comprises a painted or coated textured surface, and the third region 40 comprises a polished metallic surface, the fifth region 60, when comprising a polished surface 62 that is painted or coated, may provide enhanced definition of the third region 40, imparting more visual distinction or “pop” than might otherwise be the case, particularly if the paint or coating covering the first region 20 and fifth region 60 is dark, i.e., black, brown, gray, etc., and the third region 40 is silver in appearance. Employing a fifth region 60 that is polished rather than textured may also assist in more readily defining the forward boundary 72 of the third region 40. As is subsequently described, the third region 40 may be masked, for example, with a liquid mask prior to painting or coating the remainder of the article such as the club head 10. It may be possible to achieve a sharper forward boundary 72 if the fifth region 60 is smooth, i.e., polished, than may be possible if the fifth region 60 is rough or textured, as a smoother surface may more readily permit effective masking and avoid “bleeding” of a paint or coating that is possible by masking a rougher or textured surface.

In a preferred aspect, the fifth region 60 may be of substantially uniform width, of about 1 mm or less, and the third region 40 may be of substantially uniform width of about 2 mm or less. Other variations are of course possible. For example, the third region 40 and/or fifth region 60 may be of variable width along their length. Although only a third region 40 comprising, for example, a polished metallic strip is illustrated, multiple third regions 40 may be used, with each being separated by a painted and/or coated and/or textured region, thereby creating a multiple striping effect.

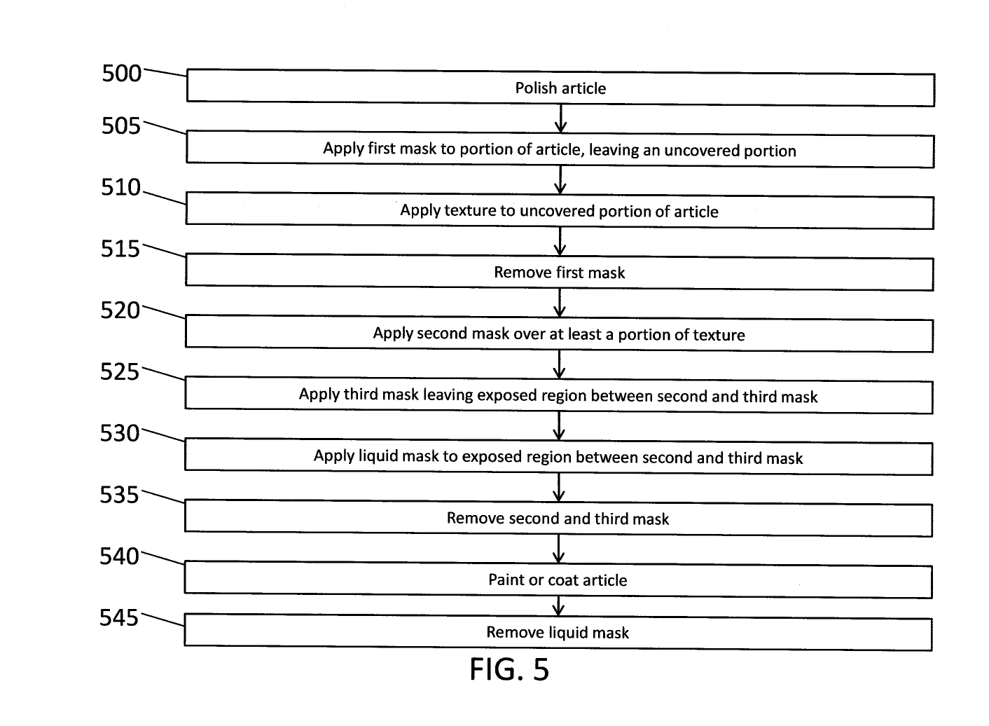

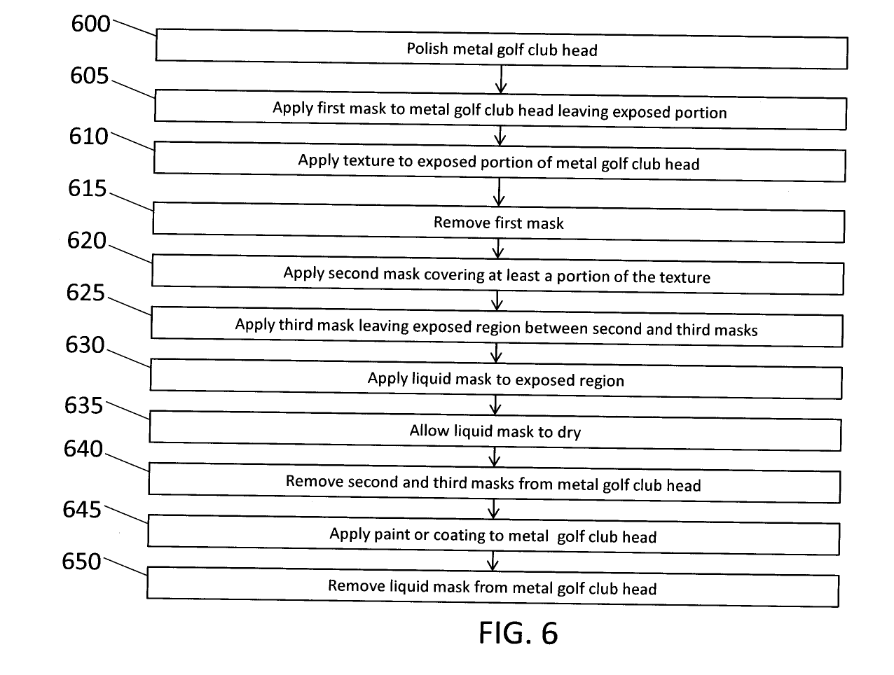

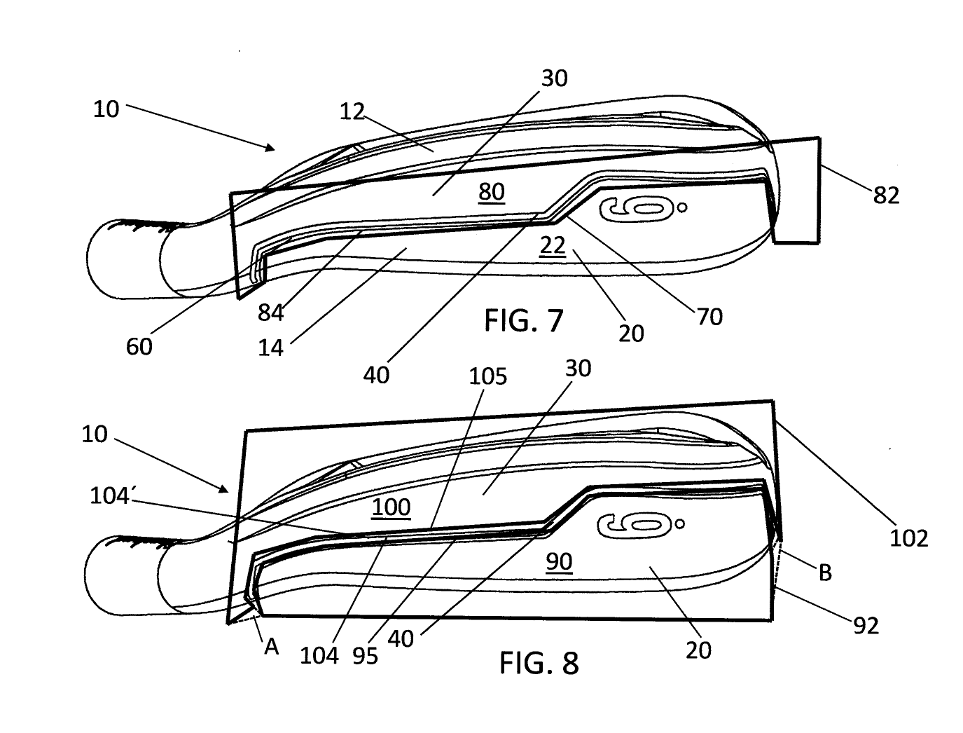

Another aspect of the disclosure, set forth in FIGS. 5 and 6, with reference to FIGS. 7 and 8, comprises methods of making a painted or coated article, such as a golf club head. In one aspect, illustrated in FIG. 5, at operation 500 an article or a portion thereof, such as a sole and/or face and/or back of a golf club head may be polished, for example, by nickel plating a golf club head and/or by subjecting a metal golf club head to a polishing step using, for example, a buffing wheel and/or liquid polish. It should be understood, however, that a polished surface, or one that appears polished without need for buffing, is within the meaning of “polished” as used herein. Thus, for example plating with a highly reflective material such as chrome plate would also comprise “polished” as that term is used herein. Such plating may be performed using any known technique, including electroplating, vapor deposition, etc.

At operation 505, a first mask 80, represented schematically by the bold outline 82 of FIG. 7, may be applied to at least a portion of the article, for example, a portion of the sole 14 or other portion of the golf club head 10. The first mask 80 may cover a first portion of the sole, for example, the second region 30, third region 40, and fifth region 60 of FIGS. 1-4, and 7, and may leave uncovered a second portion of the sole, for example the first region 20 of FIGS. 1-4, and 7. The first mask 80 may be applied proximate the back 12 of the golf club head 10, or in any other desired location of the golf club head 10 to be shielded from texturing. The first mask 80 may have an edge 70 substantially corresponding to a desired texture boundary, as represented in FIGS. 1, 4, and 7. The edge 70 need not be a straight line, and may comprise line segments, curves, angles, etc.

At operation 510, a texture may be applied to the uncovered portion of the article, i.e., second portion of the sole, for example, the first region 20 of FIGS. 1-4, and 7, thereby forming a textured region having a texture boundary defined by the first mask 80. In this example, the textured region may comprise the textured surface 22 of FIGS. 1-4, and 7, and may be defined by a texture boundary 84 as represented schematically by edge 70 of FIG. 7. In this aspect, the texture boundary 84 may substantially conform to, i.e., be defined by, the edge 70 of the first mask 80. This edge 70 may be achieved using a first mask 80 comprising, for example, die-cut masking tape creating an edge 70 having the profile illustrated in FIGS. 1, 4, and 7. The texture may alternatively, or additionally, be applied to at least a portion of the face 16, for example, the fourth region 50 illustrated in FIG. 3. The texture may be applied using, for example, one or more of a sandblasting, a chemical etching, a grinding, and/or a tumbling step.

At operation 515, the first mask 80 may be removed from the article, for example the golf club head 10, by peeling the first mask 80 therefrom. Other methods of mask removal may include pressure washing, use of pressurized air, etc.

At operation 520, a second mask 90, represented schematically by the bold outline 92 of FIG. 8, may cover at least a portion, or the entirety, of the region textured at operation 510, such as the first region 20, by being applied to the article, such as golf club head 10. In a preferred aspect, the second mask 90 may cover the entirety of the textured region. In another preferred aspect the second mask 90 may cover an offset portion, which may, for example, comprise the fifth region 60 on the sole 14. In this aspect, the second mask 90 may define an offset portion that may comprise a configuration substantially tracking the edge 70 comprising the texture boundary, but offset therefrom by a distance of, for example, 1 mm or less. The second mask 90 may thus define, in this example, the forward boundary 72 of the third region 40, best seen in FIG. 4.

At operation 525, a third mask 100, represented schematically by the bold outline 102 of FIG. 8, may be applied to article, such as the golf club head 10, and may leave an exposed region 104 on the article between the second mask 90 and third mask 100. It should be here noted that the second mask 90 and third mask 100 may optionally be joined, as represented by dashed line regions A and B, to form one mask with an opening or region 104′ corresponding to the exposed region 104, to permit placement of the second mask 90 and third mask 100 in one step. In this aspect, the opening or region 104 may be punched or die-cut in a single piece of masking material. As illustrated, the exposed region 104 as defined by the second mask 90 and third mask 100 may be defined, at least in part, by an edge 95 of the second mask 90 and an opposite edge 105 of the third mask 100. The edges 95 and 105 may be substantially straight, parallel to one another, and/or equally spaced from one another. The third mask 100 may cover at least a portion of a first polished region of the first portion of the sole 14 and may leave exposed a second polished region of the first portion of the sole 14. In the example illustrated in FIGS. 1 and 4, the third mask 100 may cover the second region 30, and may define a rearward boundary 74 of the third region 40, thereby leaving exposed the polished third region 40 which may correspond to the exposed region 104 as schematically illustrated in FIG. 8.

At operation 530, a liquid mask substantially covering the exposed region 104, such as the second polished region of the first portion of the sole 14 may be applied. In this example, the second polished region of the first portion of the sole 14 may comprise the third region 40, which in a preferred aspect may be a strip of polished metal running along the surface of the article, for example, a golf club head 10 in a generally heel-to-toe (H-T) direction. The liquid mask may resist adherence of paint, or a coating, such as PVD. For example, if the paint or coating being used is adherent to metal but not hydrophilic surfaces, the mask may comprise a hydrophilic material. Alternatively, the paint or coating may be adherent to the liquid coating. The liquid mask should, however, be adherent to the surface of the article such that it may provide masking thereto prior to removal therefrom. The liquid mask is preferably permitted to dry, which may be encouraged with heat, air, of a combination thereof.

At operation 535, the second mask 90 and the third mask 100 may be removed from the article, such as the golf club head 10. This may then expose regions, such as the first region 20, the second region 30, the fourth region 50, and/or the fifth region 60, for painting or coating thereof, while retaining the now dry liquid mask covering the third region 40 to prevent paint or coating adherence thereto.

At operation 540, the article may be painted, for example, by applying a paint, or coated, such as using PVD, to the golf club head 10, for example, to substantially the entire sole 14, back 12, face 16, and/or hosel 17. In this aspect, an article having a substantially uniform color, for example, as is possible using a PVD coating, may be achieved in one PVD coating step, while retaining an uncoated region, such as the third region 40, as a contrasting color or surface, such as a polished metallic surface. The paint or coating may be applied using known methods, including spray painting, electrostatic coating, brushing, physical vapor deposition, etc. Once applied, the paint or coating may be allowed to dry.

At operation 545, the liquid mask may be removed from the article, for example, from the second polished region of the first portion of the sole 14, in this example, the third region 40. In this operation, a highly polished metallic surface, such as polished metallic surface 48 may be achieved, while also achieving polished and/or textured painted or coated surfaces with sharp lines of demarcation, as illustrated in FIG. 4. In this operation, the liquid mask may be removed, for example, by placing the golf club head 10 in a solvent bath, with pressure washing, etc.

Another aspect of practicing the methods disclosed herein is illustrated in FIG. 6. In this aspect, at operation 600, a metal golf club head 10 may be polished, for example, by polishing a sole 14 of the metal golf club head 10. The metal golf club head 10 may comprise the sole 14, a face 16, and a back 12.

At operation 605, a first mask 80 may be applied to the metal golf club head 10, for example, by applying the first mask 80 to the sole 14. The first mask 80 may cover a rearward portion of the sole 14, and may leave uncovered a frontal portion of the metal golf club head 10 comprising an uncovered portion of the sole 14 and an uncovered portion of the face 16. The first mask 80 may comprise a frontal border, which may comprise the edge 70 of the mask 80, running in a generally heel-to-toe (H-T) direction of the metal golf club head 10.

At operation 610, a texture may be applied to the metal golf club head 10, for example, by sand-blasting the frontal portion of the metal golf club head 10, thereby forming a textured region on the uncovered portion of the sole 14 and the uncovered portion of the face 16. The textured region may have a texture boundary 84 defined by the frontal border or edge 70 of the first mask 80.

At operation 615, the first mask 80 may be removed from the metal golf club head 10.

At operation 620, a second mask 90 may be applied to the metal golf club head 10, for example, by applying the second mask 90 to cover at least a portion of the textured region. The second mask 90 may also cover an offset region of the rearward portion of the sole 14, the offset region being rearward of the texture boundary 84, while leaving exposed the third region 40. The offset region may comprise the fifth region 60, previously described with reference to FIGS. 1-4.

At operation 625, a third mask 100 may be applied to the metal golf club head 10, for example, by applying the third mask 100 to cover at least a portion of the rearward portion of the sole 14. This operation may leave exposed between the second mask 90 and third mask 100 a region which may be a strip region. The strip region may comprise the third region 40 previously described.

At operation 630, a liquid mask may be applied to the metal golf club head 10, for example, by applying the liquid mask to substantially cover the exposed region between the second mask 90 and third mask 100, which may be a strip region.

At operation 635, the liquid mask may be allowed to dry.

At operation 640, the second mask 90 and the third mask 100 may be removed from the metal golf club head 10, for example, from the sole 14.

At operation 645, a paint or coating may be applied to the metal golf club head 10, for example, by applying paint or PVD to the sole 14 and face 16. The paint or coating may be substantially non-adherent to the liquid mask.

At operation 650, the liquid mask may be removed from the metal golf club head 10, for example, by removing the liquid mask from the strip region.

It should be understood that the masks, such as masks 80, 90, and 100 illustrated herein, are illustrated schematically and not necessarily to scale or with the same contours as would be achieved using, for example, known die-cutting techniques to obtain a mask with borders precisely matching the borders of the product and surfaces to be masked, textured, coated, or painted. For ease of reference and convenience in describing features or underlying regions, such masks 80, 90, and 100 are illustrated as clear, such as would be achieved using clear masking tape or appliqués, but could as well be opaque or translucent.

The masking materials described herein, for example the first mask 80, second mask 90, and third mask 100, may comprise any known masking material, such as masking tape. It should be here noted that such masks may, in the case of some coating processes, such as PVD, be exposed to extremely high temperatures, and accordingly should be fabricated of materials capable of withstanding extreme heat, which materials are known to those of ordinary skill in the art of applying PVD and other coatings. Such masks may be fabricated using known methods, including die-cutting, slitting, stamping, and the like, in order to achieve masks having configurations designed to mask at least a portion of an article and leave unmasked at least another portion of the article in order to perform texturing, painting, coating, and/or additional masking steps. Such masks may be applied to the article using known methods, including hand application and automated application. While liquid mask has been described herein, it will be understood that other materials and techniques for masking may be used in place of the liquid mask, including, for example, by applying a layer of liquid adhesive to the area to be masked, for example, by spray coating, and then applying a powdered coating to the adhesive and allowing it to dry. Such a mask may be removed, for example, with a pressure wash or solvent bath.

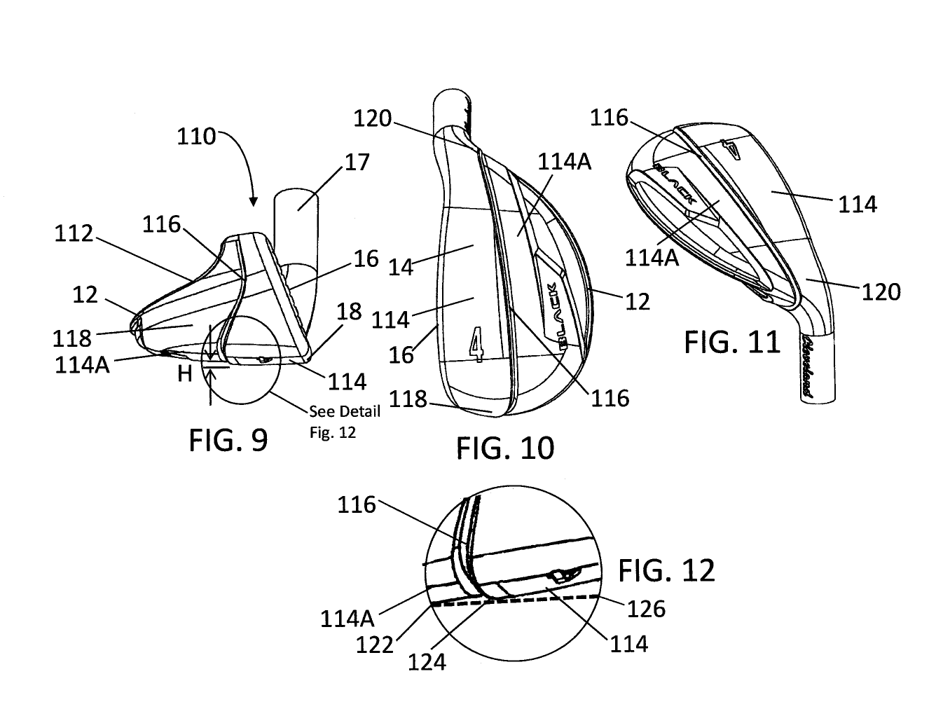

Another aspect of the disclosure is illustrated in FIGS. 9-12, relating to a golf club head, generally 110, which may comprise a wood-type golf club head, a hybrid-type golf club head, an iron-hybrid type golf club head, an iron-type golf club head, a wedge-type golf club head, or a putter-type golf club head. In the aspect, the golf club head 110 may comprise a sole 14 that is split into two or more sections, in this case, a forward section 114, in other words, a region more proximate the face 16, and a rearward section 114A, in other words, a region that is more proximate the back 12. As best seen in FIG. 12, the forward section 114 may be split from the rearward section 114A by a groove, channel, or other discontinuity 116. As seen in FIGS. 9-11, this groove 116 may run from the toe region 118 to the heel region 120 of the golf club head 110. The groove 116 may assist in visually indicating and/or distinguishing the forward section 114 from the rearward section 114A. The golf club head 110 illustrated in FIGS. 9-12 may include a scooped back or crown 112, which may assist in lowering the golf club head 110's center of gravity and/or moving the center of gravity rearward, which may improve its playability.

As is known, many golfers close their club head too much at address, which can lead to lower launch angle, less distance, slicing, among other detriments to a good golf shot. Too much closing is especially acute with hybrids and hybrid irons. As further illustrated in FIGS. 9-12, the rearward section 114A may be recessed from the forward section 114. As illustrated in FIG. 9, this offset may comprise a height “H” indicated by double arrows. As further illustrated in FIG. 12, the offset may enable the club head 110 to rock back at address when placed on the ground, with one or more contact points 122, 124 touching the ground, indicated by broken line 126. The height “H” of the offset may be varied to vary the degree to which the golf club head 110 tends to rock back at address. The weighting of the golf club head 110, for example, providing sufficient rear weighting, may also contribute to causing the golf club head 110 to rock back at address to open the face 16 to the recommended degree.

The golf club head 110 of FIGS. 9-12 may include the other features or elements described herein with respect to FIGS. 1-8, particularly those features or elements relating to the coating or texturing of various surface regions thereof and the related method. It is also contemplated that the golf club head 110 of FIGS. 9-12 may not include such features or elements.

The methods and apparatus described herein are exemplary only. For example, while exemplary embodiments described herein may reference applications of texture, paint, a coating, a polish, or a mask with respect to a sole or a face of a golf club head, it should be understood that the disclosure is intended to include such applications to other products and other regions of golf club heads, including, by way of example, the face, back, crown, sole, skirt, heal, and/or toe thereof, and/or providing a feature line or reflective strip that transitions up to the skirts of a wood-type golf club head.

As used herein, the term “article” means any product or surface thereof that is capable of receiving a polish, a texture, a coating, and/or a paint, for example, metal, wood, plastic, glass, stone, ceramic, and the like. The methods disclosed herein may, accordingly be employed on not only a golf club head manufactured of such materials, but also, for example, automobiles and automotive components, furniture, building materials, toys, dishware, glassware, aircraft, machinery, coinage, vending machines, and so on. Thus, while the description herein describes apparatus and methods primarily in the context of golf club heads and their manufacture, such disclosure is exemplary, and not intended to be so limited.

As used herein, the term “paint” or “painted” includes not only application of paints, such as oil or water-based paints, but also other applications of coatings that may impart color or finish such as gloss, semi-gloss, or matt finishes, including by way of example, anodized treatment processes, printing, silk screening, and the like.

Unless otherwise indicated, all numbers expressing quantities should be understood to have minor manufacturing tolerances, and accordingly, as used in the specification and claims are to be understood as being modified in all instances by the term “about.” Thus, unless indicated to the contrary, the numerical parameters set forth in the specification and attached claims are approximations that may vary depending upon the desired properties sought to be obtained.

At the very least, and not as an attempt to limit the application of the doctrine of equivalents to the scope of the claims, each numerical parameter should at least be construed in light of the number of reported significant digits and by applying ordinary rounding techniques. Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in their respective testing measurements.

The terms “a,” “an,” “the” and similar referents used in the context of describing the embodiments are to be construed to cover both the singular and the plural, unless otherwise indicated herein or clearly contradicted by context. Recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein is intended merely for clarification and does not pose a limitation on the scope of the disclosure. No language in the specification should be construed as indicating any non-claimed element essential to the practice of any embodiments discussed herein.

While different features or aspects of an embodiment may be described with respect to one or more features, it is to be understood that a singular feature so described may comprise multiple elements, and that multiple features so described may be combined into one element without departing from the spirit of the disclosure presented herein. Furthermore, while methods may be disclosed as comprising one or more operations, it is to be understood that a single operation so described may comprise multiple steps, and that multiple operations so described may be combined into one step without departing from the spirit of the disclosure presented herein.

Groupings of alternative elements or embodiments disclosed herein are not to be construed as limitations. Each group member may be referred to and claimed individually or in any combination with other members of the group or other elements found herein. It is anticipated that one or more members of a group may be included in, or deleted from, a group for reasons of convenience and/or patentability. When any such inclusion or deletion occurs, the specification is deemed to contain the group as modified thus fulfilling the written description of all Markush groups used in the appended claims.

Specific embodiments disclosed herein may be further limited in the claims using “consisting of” or and “consisting essentially of” language. When used in the claims, whether as filed or added per amendment, the transition term “consisting of” excludes any element, step, or ingredient not specified in the claims. The transition term “consisting essentially of” limits the scope of a claim to the specified materials or steps and those that do not materially affect the basic and novel characteristic(s). Embodiments so claimed are inherently or expressly described and enabled herein.

In closing, certain embodiments are described herein, including the best mode known to the inventors. Of course, variations on these described embodiments will become apparent to those of ordinary skill in the art upon reading the foregoing description. The inventor expects skilled artisans to employ such variations as appropriate, and the inventors intend for the invention to be practiced otherwise than specifically described herein. Accordingly, this application includes all modifications and equivalents of the subject matter recited in the claims appended hereto as permitted by applicable law. Moreover, any combination of the above-described elements in all possible variations thereof has been contemplated by the inventors and within the scope of the disclosure unless otherwise indicated herein or otherwise clearly contradicted by context. That is, it is to be understood that the embodiments disclosed herein are illustrative of the principles of the invention, and therefore, alternative configurations may be utilized in accordance with the teachings herein. Accordingly, the present invention is not limited to that precisely as shown and described.

1-45. (canceled)

46. A method comprising:
(a) masking a first sole portion of a sole of a golf club head with a first mask, the first sole portion having a first texture;
(b) texturing a second sole portion of the sole of the golf club head to form a second texture different from the first texture such that a texture boundary is formed between the first sole portion and the second sole portion;
(c) removing the first mask;
(d) masking the second sole portion and a first region of the first sole portion adjacent to the texture boundary with a second mask;
(e) masking a second region of the first sole portion offset from the first region with a third mask such that a third region of the first sole portion between the first region and the second region is unmasked;
(f) masking the third region using a fourth mask comprising an anti-PVD material;
(g) removing the second and third masks;
(h) applying a PVD layer to the sole of the golf club head such that the second sole portion and the first region and the second region of the first sole portion comprise the PVD layer; and
(i) removing the fourth mask to expose the third region absent the PVD layer, the third region at least partially separating the first region and the second region.

47. The method of claim 46, wherein the first, second, and third masks comprise an adhesive material such as a masking tape.

48. The method of claim 46, wherein the fourth mask comprises a liquid material.

49. The method of claim 46, wherein the texture boundary extends in a generally heel to toe direction and the first region of the first sole portion extends 1 mm or less in a generally front to rear direction from the texture boundary.

50. The method of claim 46, wherein the second sole portion and the first region, the second region, and the third region of the first sole portion all extend in a generally heel to toe direction.

51. The method of claim 46, wherein the second sole portion is one of nearer or further away from a striking face of the golf club head than the first sole portion.

52. The method of claim 51, wherein the forward-most point of one of the second sole portion and the first sole portion is adjacent the striking face.

53. The method of claim 46, wherein the second mask and the third mask are formed as a single mask with an opening between them for exposing the third region.

54. The method of claim 46, wherein the texture boundary follows a substantially linear path.

55. The method of claim 46, wherein the texture boundary follows a substantially non-linear path.

56. The method of claim 46, wherein the third sole portion is metal and is polished prior to masking the third sole portion, and following removal of the fourth mask reveals a metallic strip.

57. The method of claim 56, wherein the third sole portion is polished prior to masking the first sole portion.

58. The method of claim 57, wherein the entire sole of the golf club head is polished prior to masking the first sole portion.

59. A method comprising:
(a) polishing at least a first sole portion of a sole of a golf club head to form a polished texture;
(b) masking the first sole portion with a first mask;
(c) texturing a second sole portion of the sole of the golf club head to form a texture different from the polished texture such that a texture boundary is formed between the first sole portion and the second sole portion;
(d) removing the first mask;
(e) masking the second sole portion and a first region of the first sole portion adjacent the texture boundary with a second mask;
(f) masking a second region of the first sole portion offset from the first region with a third mask such that a third region of the first sole portion between the first region and the second region is unmasked;
(g) masking the third region using a fourth mask;
(h) removing the second and third masks;
(i) applying a coating layer to the sole of the golf club head such that the second sole portion and the first region and the second region of the first sole portion comprise the coating layer; and
(j) removing the fourth mask to expose the third region absent the coating layer, the third region at least partially separating the first region and the second region.

60. The method of claim 59, wherein the first, second, and third masks comprise an adhesive material such as a masking tape.

61. The method of claim 59, wherein the fourth mask comprises a liquid material.

62. The method of claim 59, wherein the texture boundary extends in a generally heel to toe direction and the first region of the first sole portion extends 1 mm or less in a generally front to rear direction from the texture boundary.

63. The method of claim 59, wherein after step (j), the third region comprises the polished texture of the at least the first sole portion immediately after step (a).

64. A method implemented on a sole of a golf club head comprising a first sole portion having a first texture and a second sole portion having a second texture different from the first texture such that a texture boundary is formed therebetween, the method comprising:
(a) masking the second sole portion and a first region of the first sole portion adjacent the texture boundary with a first mask;
(b) masking a second region of the first sole portion offset from the first region with a second mask such that a third region of the first sole portion between the first region and the second region is unmasked;
(c) masking the third region using a third mask comprising an anti-PVD material;
(d) removing the first and second masks;
(e) applying a PVD layer to the sole of the golf club head such that the second sole portion and the first region and the second region of the first sole portion comprise the PVD layer; and
(f) removing the fourth mask to expose the third region absent the PVD layer, the third region at least partially separating the first region and the second region.

65. The method of claim 64, wherein the texture boundary extends in a generally heel to toe direction and the first region of the first sole portion extends 1 mm or less in a generally front to rear direction from the texture boundary.
